(19) United States
(12) Patent Application Publication
(10) Pub. No.: US 2014/0300374 A1
(43) Pub. Date: Oct. 9, 2014

(54) METHOD AND APPARATUS FOR MEASUREMENT OF A DC VOLTAGE

(71) Applicants: Gordon McKenzie, Kirkcaldy (GB); Paul Record, Cupar (GB)

(72) Inventors: Gordon McKenzie, Kirkcaldy (GB); Paul Record, Cupar (GB)

(73) Assignee: ULTRA ELECTRONICS LIMITED, Middlesex (GB)

(21) Appl. No.: 14/239,522

(22) PCT Filed: Aug. 17, 2012
(86) PCT No.: PCT/GB2012/000666

§ 371 Date: Jun. 5, 2014

(30) Foreign Application Priority Data
Aug. 18, 2011 (GB) 1114258.5

(51) Int. Cl. G01R 27/26; G01R 19/00

(52) U.S. Cl. CPC G01R 27/2605; G01R 19/0084
USPC 324/658

(57) ABSTRACT

Apparatus for measurement of a DC voltage of a DC voltage source. An electrode forms a capacitive connection with the DC voltage source. A non-linear capacitor has a first node connected to the electrode. An initial voltage source is arranged to generate an initial voltage. A switch is arranged to selectively apply the initial voltage to a second node of the non-linear capacitor. A voltage sensor is arranged to measure the voltage of the second node of the non-linear capacitor and a processor is programmed to deduce the DC voltage of the DC voltage source by analysing the rate of decay of the measured voltage.

### FIELD OF THE INVENTION

The present invention relates to a method and apparatus for measurement of a DC voltage by means of a capacitive non-contact arrangement.

### BACKGROUND OF THE INVENTION

Non-contact measurement of the fundamental electrical quantities of voltage and current is desirable in many situations, allowing measurements to be made without physical access to the electrical conductors in question. Measuring an AC voltage on a conductor is relatively straightforward—placing an electrode in close proximity to the insulated conductor causes a capacitance to be formed between the electrode and the conductor being monitored, through which an alternating current will flow that is in proportion to the peak to peak AC voltage, assuming that the electrode is maintained at a known potential. However, the problem of measuring DC voltages in a similar situation has received relatively little research attention.

One method is described in McKenzie, G and Record, P, “Non-contact voltage measurement using electronically varying capacitance”. Electronics Letters, February 2010. 46(3): p. 214-216). This work used an electronically varying capacitance placed in series with the linear coupling capacitance from source to electrode. The key element of the electronically varying capacitor was a transconductor, which was used to inject a controlled quantity of additional in-phase current without changing the voltage across the effective capacitance. The result was a change in the current vs. voltage curve and therefore a change in capacitance, which was controlled by varying the amount of additional current sourced or sunk by the transconductor. However, this method proved incapable of giving a measureable change in output for a change in input voltage when the linear coupling capacitance between source and electrode was of the order required. The published results show a measureable response only for Cᵢₙ values down to 1 nF while in the real electrode-around-insulation situation the value of Cᵢₙ is typically 10-100 pF.

### SUMMARY OF THE INVENTION

A first aspect of the invention provides apparatus for measurement of a DC voltage of a DC voltage source, the apparatus comprising an electrode for forming a capacitive connection with the DC voltage source; a non-linear capacitor having a first node connected to the electrode; an initial voltage source arranged to generate an initial voltage; a switch arranged to selectively apply the initial voltage to a second node of the non-linear capacitor; a voltage sensor arranged to measure the voltage of the second node of the non-linear capacitor; and a processor programmed to deduce the DC voltage of the DC voltage source by analysing the rate of decay of the measured voltage.

A further aspect of the invention provides a method of measuring a DC voltage of a DC voltage source, the method comprising arranging an electrode to form a capacitive connection with the DC voltage source; providing a non-linear capacitor having a first node connected to the electrode; generating an initial voltage with an initial voltage source; closing a switch to connect the initial voltage source to a second node of the non-linear capacitor so the initial voltage is applied to the second node of the non-linear capacitor; opening the switch to disconnect the non-linear capacitor from the initial voltage source; measuring the voltage of the second node of the non-linear capacitor after the switch has been opened; and deducing the DC voltage of the DC voltage source by analysing the rate of decay of the measured voltage.

The present invention provides a method and associated apparatus which is capable of accurately measuring the DC voltage by a capacitive connection with a relatively low capacitance, and thus provides an improvement over the method described in McKenzie, G and Record, P, “Non-contact voltage measurement using electronically varying capacitance”. Electronics Letters, February 2010. 46(3): p. 214-216).

The voltage of the second node of the non-linear capacitor may be measured with respect to ground, or with respect to any other known voltage. The voltage sensor may be coupled directly to the second node of the capacitor, or it may be coupled indirectly to the second node via one or more additional circuit components.

Preferably biasing means, such as a bias voltage source and a switch, is arranged to selectively apply a bias voltage to the first node of the non-linear capacitor. Typically the bias voltage which is applied to the first node of the non-linear capacitor is a reverse bias voltage with a polarity opposite to the polarity of the initial voltage which is applied to the second node of the non-linear capacitor. Optionally the biasing means may be arranged to sequentially apply negative and positive bias voltages to the first node of the non-linear capacitor.

After the non-linear capacitor has been pre-biased by applying the bias voltage to the first node of the non-linear capacitor, the bias voltage is typically removed from the first node of the non-linear capacitor before the switch is opened to disconnect the non-linear capacitor from the initial voltage source.

The non-linear capacitor may be a varicap diode, a non-compensated multilayer ceramic capacitor or other capacitor which uses a ferroelectric material, an ionic polymer/metal composite (IPMC) capacitor, an on chip metal-oxide-semiconductor (MOS) capacitor, or any other suitable capacitor with a suitably non-linear capacitance (i.e. a capacitance which varies with respect to voltage).

Preferably the non-linear capacitor has a capacitance which is less than the capacitance of the capacitive connection with the DC voltage source.

Typically the capacitance of the capacitive connection with the DC voltage source is less than 1 nf, more typically it is less than 500 pf, and most preferably it is less than 100 pf.

Typically the non-linear capacitor has a capacitance which is less than 100 pf, more typically less than 20 pf, and most preferably it is less than 10 pf.

The switch may be a mechanical switch but more preferably it is a transistor switch.

The rate of decay of the measured voltage may be analysed in a number of ways, such as measuring the time taken for it to decay to a threshold level, capturing the decay curve using a digital oscilloscope and processing the data from it, measuring the voltage at precisely specified times after opening the switch, or any other suitable method.

### BRIEF DESCRIPTION OF THE DRAWINGS

Embodiments of the invention will now be described with reference to the accompanying drawings, in which:

FIG. 1(a) illustrates a physical measurement arrangement according to an embodiment of the present invention;

FIG. 1(b) is an equivalent circuit of the measurement arrangement of FIG. 1(a);

FIG. 2 is a charge/discharge circuit for a single capacitor;

FIG. 3 is a charge/discharge circuit with a series non-linear capacitor;

FIG. 4 is a graph showing modelled decay curves using a ZC830 varicap with Cin=33 pF;

FIG. 5 is a graph showing modelled times to decay to 90%, 50% and 10% threshold levels, for a varicap with Cin=33 pF;

FIG. 6 is a graph showing modelled times to decay to 90%, 50% and 10% threshold levels, for a varicap only;

FIG. 7 is a graph showing modelled decay curves using a multilayer ceramic capacitor with Cin=22 nF;

FIG. 8 is a graph showing modelled times to decay to 90%, 50% and 10% threshold levels, for an MLCC with Cin=22 nF;

FIG. 9 is a generic circuit illustrating apparatus according to a first embodiment of the present invention, including a generic circuit for measuring time delays;

FIG. 10 is a graph showing measured decay times from Circuit Tests, for a varicap only;

FIG. 11 is a graph showing measured decay times for a varicap in series with a parallel combination of Cin and leakage resistance;

FIG. 12 is a graph showing drift in measurements with no leakage or biasing circuitry;

FIG. 13 is a generic circuit illustrating apparatus according to a second embodiment of the present invention, including capacitively coupled biasing;

FIG. 14 is a timing diagram for the circuit of FIG. 13;

FIG. 15 is a graph showing measured decay times for a circuit with capacitively coupled biasing and no added leakage resistance;

FIG. 16 is graph showing drift with capacitive biasing circuitry added;

FIG. 17 is a graph showing measured decay time using an MLCC as the non-linear element and Cin=22 nF;

FIG. 18 shows a modified MLCC circuit including direct biasing;

FIG. 19 is a graph showing MLCC circuit test results with pre-biasing;

FIG. 20 is a graph showing circuit test results with a varicap and real electrode-around-conductor coupling capacitance; and

FIG. 21 is a schematic diagram showing the apparatus of FIG. 9, 13 or 18 connected to an output device and ground connection.

### DETAILED DESCRIPTION OF EMBODIMENT(S)

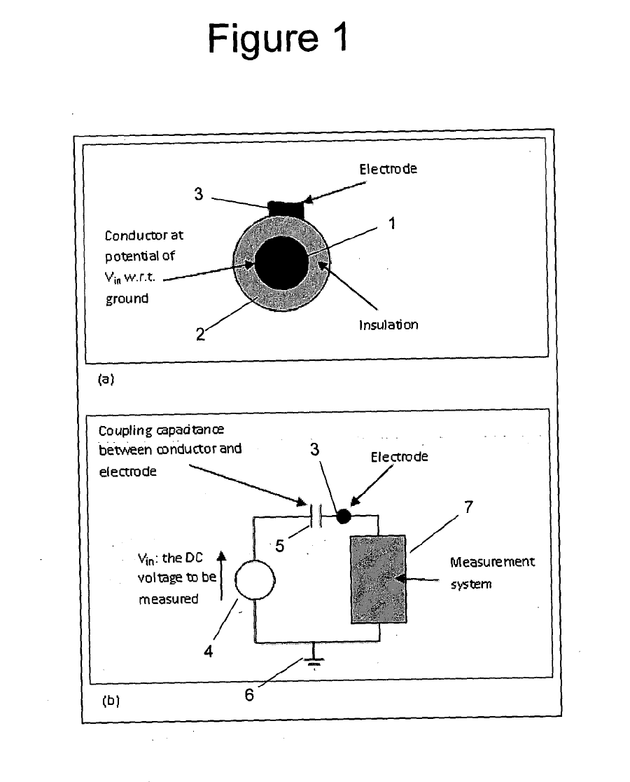

FIG. 1(a) shows a wire 1 surrounded by an insulating sheath 2. An electrode 3 is placed as close as possible to the wire 1 to form a capacitive connection with it. FIG. 1(b) shows the equivalent circuit of the arrangement of FIG. 1(a) with the wire 1 illustrated as a voltage source 4 and the capacitive connection illustrated as a capacitor 5. The electrode 3 is connected to a measurement system 7 which deduces the DC voltage Vᵢₙ of the conductor 1.

FIG. 1(b) assumes that a ground connection 6 is common to both the measurement system 7 and the voltage source 4 being monitored. This is a realistic representation for most systems, when some arbitrary ground reference 6 is available. However, it should be noted that should it be necessary to do so, it is also possible to make the device fully differential to measure the voltage difference on two separate conductors. The only change resulting from this is that an additional coupling capacitance would be added to the equivalent circuit between the other side of the voltage source 4 being measured and the ground of the measurement system 7, removing the common ground connection. Electrically this is simply an additional capacitor in series, which acts to reduce, but not eliminate, the capacitance Cᵢₙ. of the capacitor 5.

The measurement system 7 works fundamentally on the principle of conservation of charge when capacitors are connected in series across a voltage source. For two capacitors C₁ and C₂, connected in series across a voltage source V, voltage is distributed across the capacitors as follows:

$$\begin{matrix}{V}_{{C}_{1}} = V \cdot \frac{{C}_{2}}{{C}_{1} + {C}_{2}} & ( 1 ) \\ {V}_{{C}_{2}} = V \cdot \frac{{C}_{1}}{{C}_{1} + {C}_{2}} & ( 2 )\end{matrix}$$

Also, by applying the relation Q=VC, it can be seen that the charge on both capacitors is equal.

A linear capacitor is one whose charge vs. voltage curve is a straight line through the origin, where the capacitance is a constant given by the gradient of the line. However, this is not the case with a non-linear capacitor; for this circuit element capacitance is a function of voltage, where there may or may not be hysteresis, depending on the dielectric material used. Non-linear capacitors have been known for many years, with charge and discharge behaviour described in Macdonald, J R and Brachman, M K, “The Charging and Discharging of Non-linear Capacitors”. Proceedings of the IRE, January 1955. 43(1): p. 71-78.

In the situation where it is required to measure the voltage on an insulated conductor without removing the insulation, connecting a second (linear) capacitor in series with the coupling capacitance of the insulation would give a situation where the above equations are valid. However, in order to measure voltage on the conductor, it is necessary to make the effective capacitance between the conductor and a measurement node non-linear by placing a voltage-dependent capacitor in series with the linear coupling capacitance. If the principle of charge conservation in series capacitors is upheld, then the resultant capacitance of the series combination is also non-linear and voltage dependent.

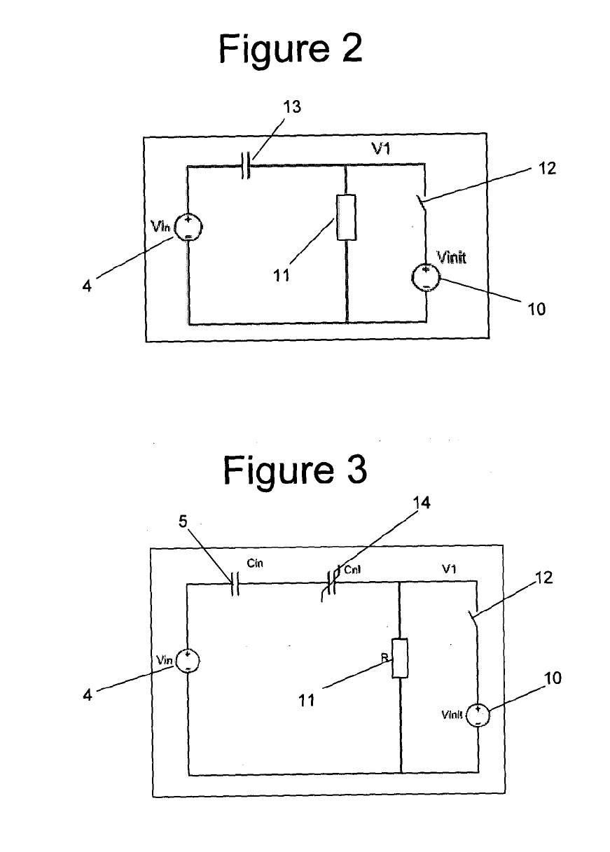

Having now established that the conductor being monitored can be connected to a measurement node via a non-linear capacitance, it is necessary to consider the charge and discharge behaviour when such capacitors are used. Firstly, consider the situation where a DC input voltage is connected across a simple R-C combination where C is linear and the other side of the capacitor is initially at a known potential. This is illustrated in FIG. 2, which shows an initial voltage source 10, a resistor 11 (with a resistance R), a switch 12 and a capacitor 13 (with a constant capacitance C). The switch 12 is initially closed, giving the condition V1=Vᵢₙᵢₜ (where V1 is the voltage on one side of the capacitor 13 and Vᵢₙᵢₜ is the voltage generated by the initial voltage source 10). Once the switch 12 opens, behaviour is dependent upon the resistance and capacitance in the circuit.

After the switch is released, the differential equation describing circuit operation is:

$${V}_{i n} = \frac{d Q}{d t} \cdot R + \frac{Q}{C} \qquad ( 3 )$$

Immediately before the switch is released, the capacitor 13 is charged to a voltage (Vᵢₙ−Vᵢₙᵢₜ), therefore the initial value of Q during the discharge phase after the switch is opened is:

Qᵢₙᵢₜ=(Vᵢₙ−Vᵢₙᵢₜ)·C (4)

Solving the differential equation yields a closed form solution for the voltage V1 as a function of time:

V1=Vᵢₙᵢₜ·exp(−t/RC) (5)

Clearly the voltage at V1 in this situation is independent of the input voltage Vᵢₙ to be measured.

FIG. 3 shows the equivalent circuit of a device according to an embodiment of the present invention, with a non-linear capacitor 14 in series with a linear coupling capacitor 5. The capacitor 5 (with a capacitance Cᵢₙ) is the input coupling capacitance through the wire's insulation 2 while the non-linear capacitor 14 (with a capacitance Cₙ₁) is the non-linear capacitive element placed in series as part of the measurement system. The capacitance Cₙ₁ is a function of the potential difference present across the non-linear capacitor 14, and therefore also a function of charge, which, at any given instant, is the same on both capacitors 5, 14. This time, the differential equation that describes the circuit after the switch 12 is opened is:

$${V}_{i n} = \frac{d Q}{d t} \cdot R + \frac{Q}{{C}_{i n}} + \frac{Q}{{C}_{nl}} \qquad ( 6 )$$

The initial value of Q during discharge is the same as the final value of Q from the charging phase when the switch is closed, and Cₙ₁ is a function of Q. Solving this differential equation yields a value of Q for all values of time, and from this the voltages across the capacitors 5, 14 and the resistor 11 can easily be found. Although a non-linear element 14 has been introduced, this is still a type of R-C circuit, and as such it should be expected that V1 will decay from Vᵢₙᵢₜ to 0 over a period of time. However, the decay characteristics are different to what would be seen in a circuit that contained only linear capacitors. In the circuit of FIG. 3 the decay depends not only on Vᵢₙᵢₜ but also upon the value of Vᵢₙ, as well as the nature of voltage-capacitance relationship of the non-linear capacitor 14. Given that the decay characteristic is a function of Vᵢₙ (the quantity being measured) the expectation is that the capacitively coupled voltage Vᵢₙ can be deduced by analysing the voltage V1 as its value decays from Vᵢₙᵢₜ to zero.

Some tests were undertaken with a polystyrene or ceramic capacitor as the coupling capacitor 5, while others used a real conductor-to-electrode capacitance formed by wrapping an electrode around the outside of a wire's insulation layer. When discussing real electrodes and their associated coupling capacitance, the particular type of wire used was Tyco's 440111-22-9. This is a standard type of wire used on aircraft, consisting of stranded wire and radiation-treated insulation, and complying with military standard MIL-W-81044. The datasheet does not give the effective dielectric constant, but using the published dimensions and measured conductor-to-electrode capacitance values, it was experimentally found to be 2.99.

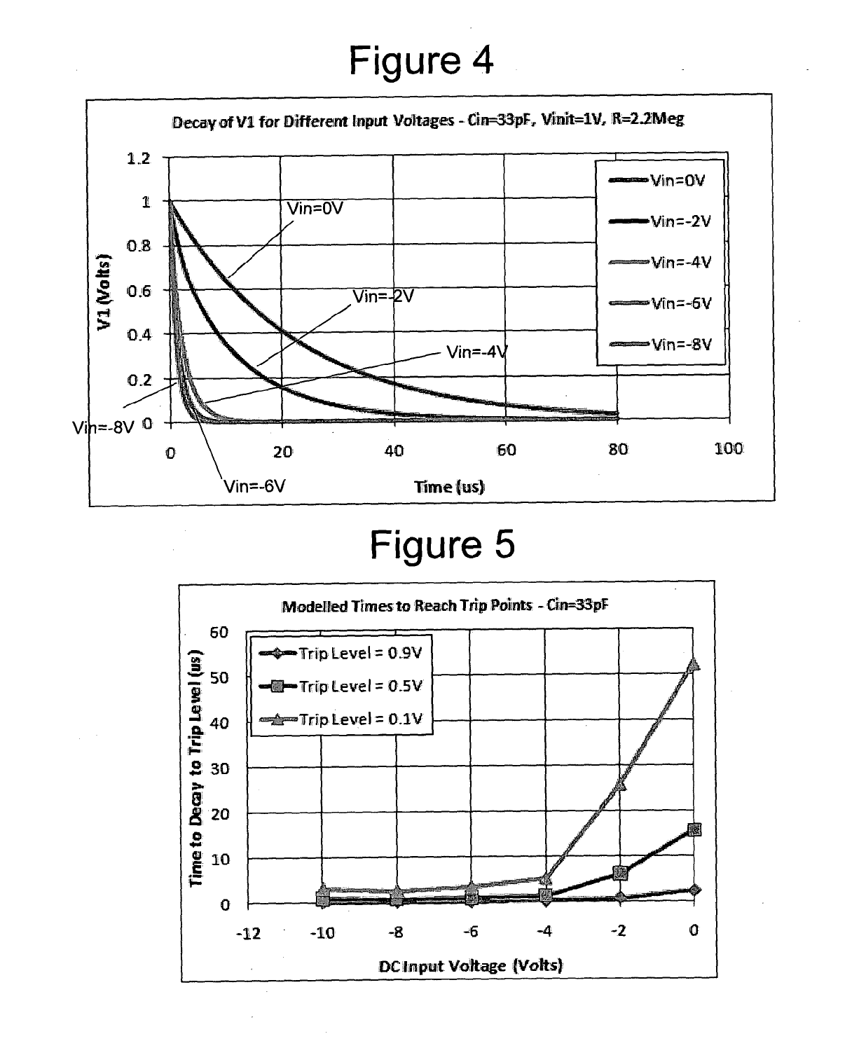

One of the most commonly available non-linear capacitance devices having a large change in capacitance with applied voltage is the varicap diode. By measurement it was found that for electrode lengths of 30-100 mm, coupling capacitances were in the range 12-40 pF. Ideally, the varicap's capacitance value, over its full range, should be comparable or less than the value of Cᵢₙ—this ensures that a significant portion of the input voltage is dropped across the sensitive element, in accordance with equations 1 and 2. With this in mind the ZC830B, with its 2-10 pF range (for reverse voltages in the range 0V to 20V), was chosen. Translating datapoints from the capacitance vs. voltage curve in the datasheet to obtain a lookup table of the Cₙ₁ vs. Q function, equation 6 was numerically solved using MATLAB's® ode45( ) function. The results of this, showing the decay characteristics for different input voltages with Cᵢₙ=33 pF, are shown in FIG. 4. For clarity, traces obtained for larger negative values of Vᵢₙ are omitted.

The results of the modelling show that, provided reverse bias is maintained (the condition for capacitance of the varicap diode being a function of voltage), then the nature of the decay in V₁, falling from Vᵢₙᵢₜ to zero, does indeed depend upon the input voltage. In general, the larger the magnitude of the negative voltage at the input (the voltage that is being measured), the shorter the time required to decay to zero. Therefore, if a trip point is set at a particular value somewhere between Vᵢₙᵢₜ and zero and the time taken for V₁ to reach the trip level is measured, then input voltage can be deduced from this time measurement. The curves of FIG. 4 are analysed in this way, with time to decay to threshold being plotted against input voltage in FIG. 5, using three arbitrary trip levels of 90% of Vᵢₙᵢₜ, 50% of Vᵢₙᵢₜ and 10% of Vᵢₙᵢₜ.

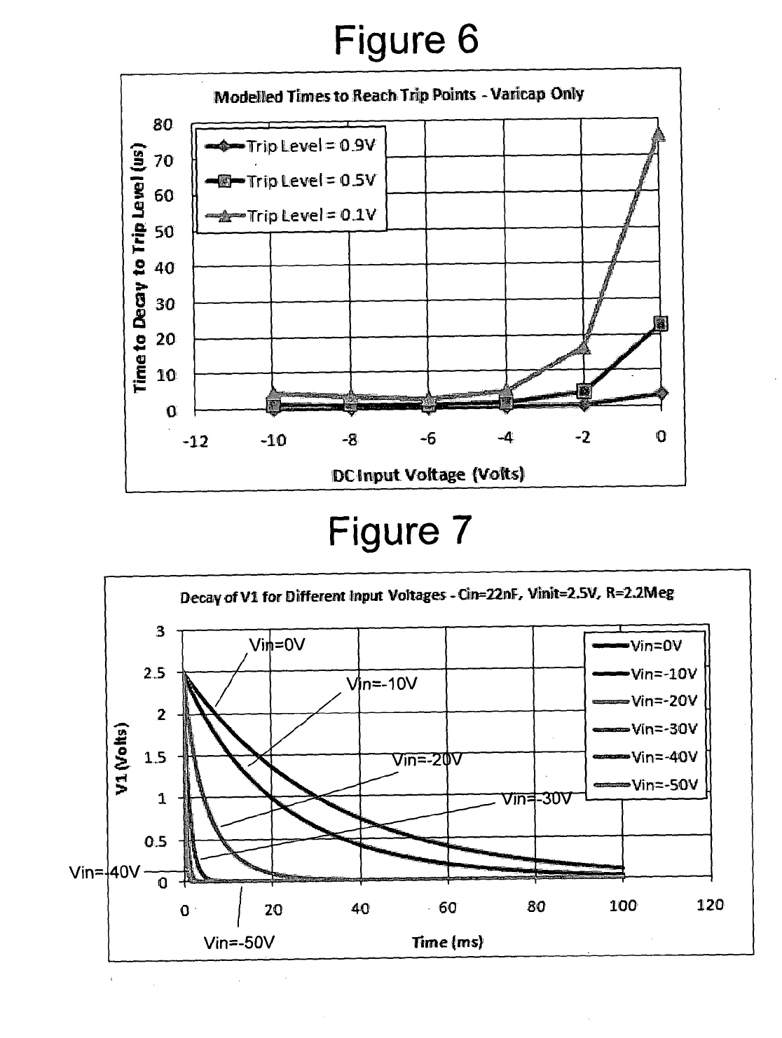

It can be seen that for all selected trip thresholds, the device is more sensitive in the region where input voltage is small and negative. A similar analysis was performed for the situation where capacitor 5 was shorted out and the input voltage connected directly to the anode of the ZC830, with the result in FIG. 6. This represents the limiting case, equivalent to having infinite Cᵢₙ. As expected, the response is larger in this situation than with Cᵢₙ=33 pF (as in FIG. 5)

So as to demonstrate that the principle holds for different varieties of non-linear capacitor and not varicaps exclusively, results were also obtained with an alternative type. Multilayer ceramic capacitors (MLCCs) are produced in large volume, and some of these have non-linear properties. In most applications, this non-linearity would be seen as a disadvantage, but for this voltage measurement system, it is helpful to have as large a non-linearity as possible. MLCCs can generally be classified into two types—compensated and non-compensated. The compensated type show very little capacitance change with applied voltage, but the non-compensated type can give a very large change, making them the more suitable choice for this application.

The non-linearity in these capacitors is due to the dielectric containing ferroelectric material; this means that the capacitor is non-linear but also means the base capacitance (the value obtained with no voltage applied) is high. 100 nF to 10 uF is typical. Although these values mean that currently available components are incapable of giving a measureable response for the input coupling capacitances of 10-100 pF seen with a real electrode-around-insulation situation, larger coupling capacitances can be used to demonstrate the principle of operation, and show that non-linear capacitors can be used for this purpose regardless of the specific property that causes the non-linearity. In addition, MLCCs of this type are often used for power supply decoupling where the non-linearity makes little difference to performance—as such, larger capacitance values are generally more suitable which helps explain why non-compensated MLCCs are not currently available with small capacitance values. The issue is not that non-linear MLCCs in the picofarad range cannot be produced, simply that until now there has been no application for such a component.

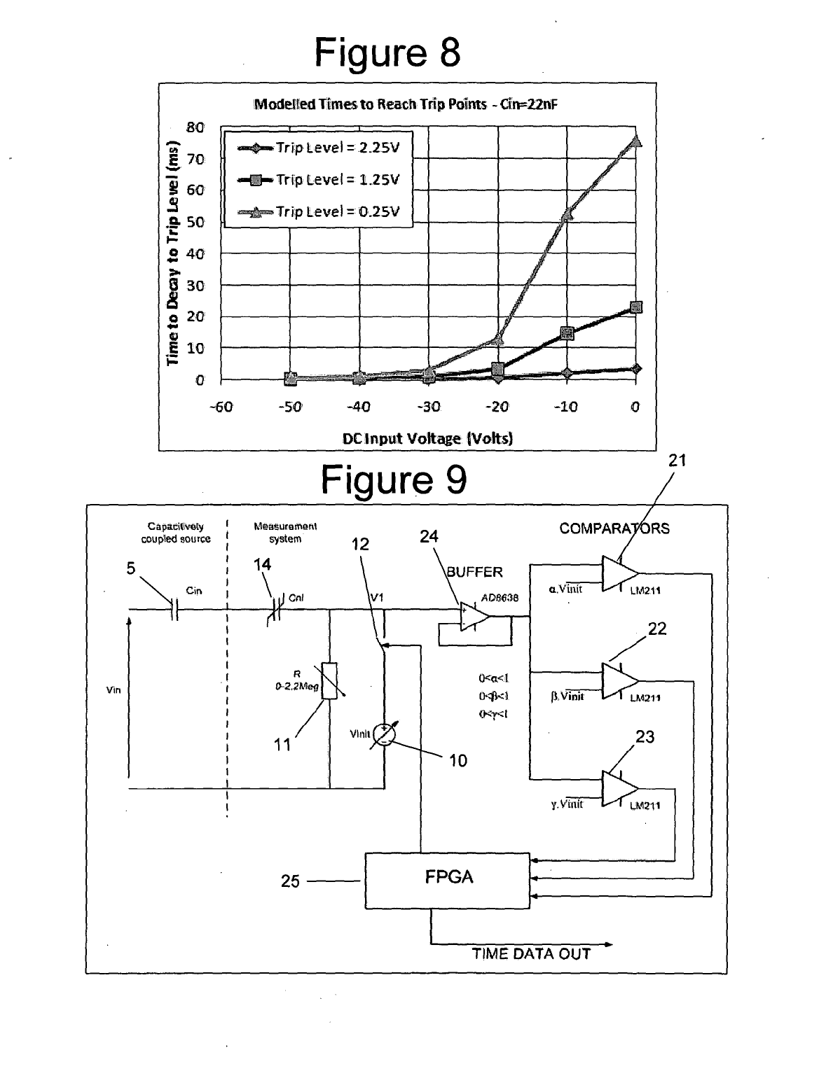

Again this was simulated using MATLAB®, with the model constructed by using the capacitance vs. applied voltage curve from the non-linear capacitor's datasheet. The component used was Murata's GRM188F51H473ZA01D—an MLCC with temperature characteristic Y5V (the characteristic that gives the largest change in capacitance with applied voltage) and capacitance of 47 nF for zero applied voltage. This component has a larger voltage rating than the varicap, meaning a larger range of input voltage is required to see a noticeable change in output. The modelled decay curves for this setup are shown in FIG. 7 with this mapping to FIG. 8, showing decay time to the appropriate thresholds.

As expected, the trend is similar to that for the varicap—the smaller the value of negative voltage, the longer the time to decay to each threshold. Once again, sensitivity, denoted by gradient in FIG. 8, is greatest in the region close to zero. The main difference is that this time the times are measured in milliseconds rather than microseconds; these much longer time values are expected since the time constant of the decay circuit is much larger due to larger capacitance values.

FIG. 9 shows the device of FIG. 3 with the switch 12 implemented with a CMOS switch to apply the initial voltage and three adjustable comparators 21, 22, 23 whose trip voltages were different proportions of Vᵢₙᵢₜ. A JFET amplifier 24 with low common mode capacitance is used to buffer the voltage V₁ before applying it to one input of each comparator 21-23. The circuit operates under control of an FPGA 25, within which the time is measured between giving the signal to close the switch and each comparator output flipping to its opposite logic level. Timing is by means of a simple digital counter and 50 MHz clock (not shown).

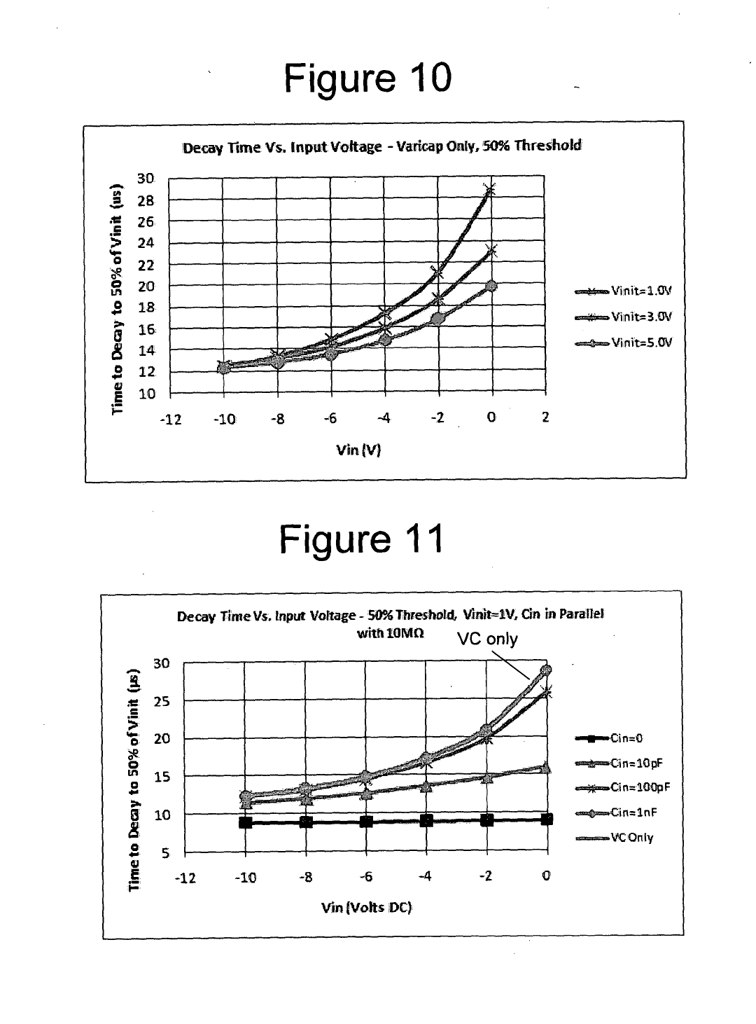

In a test phase, the non-linear capacitor 14 shown in FIG. 9 was a ZC830 varicap diode, orientated such that its anode is connected to capacitor 5 and its cathode to resistor 11 and the buffer amplifier 24. This meant that negative input voltages and positive values of Vᵢₙᵢₜ could be applied to maintain the necessary reverse bias condition, to give a situation comparable to that in simulation. Initially the circuit was tested with a short circuit placed across capacitor 5, i.e. in a situation where the input voltage was applied directly to the anode of the capacitor 14. With the threshold set at 50% of Vᵢₙᵢₜ, the graph of time to decay to threshold against DC input voltage is shown in FIG. 10. Similar graphs were obtained for 90% and 10% thresholds.

From this, it can be seen that the response is largely as predicted by theory; for a given value of Vᵢₙᵢₜ, the time to decay to the 50% threshold increases as the negative input voltage becomes smaller. Generally, this agrees with the predicted performance shown in the ‘Trip Level=0.5V’ curve of FIG. 6, with the gradient being steeper as the DC input voltage approaches zero and flatter (thus less sensitive) for large negative input voltages. In addition to this, if a larger value of Vᵢₙᵢₜ is used then the time delays are not as large, this being because a larger positive value of Vᵢₙᵢₜ means a larger voltage across the varicap. Since the ZC830 has a lower capacitance for a larger voltage, which in turn results in a smaller circuit time constant, this response is expected. These results confirm the principle of operation.

When the input voltage is coupled to the varicap through a small linear coupling capacitance, as in the real situation, the situation becomes more complicated. The varicap diode is a semiconductor device, and in most applications where it is used a DC bias is directly applied. In this application however, this is more difficult. In the situation of FIG. 9, a known DC voltage would need to be applied across the varicap 14, something that would prevent intended circuit operation. To operate as intended therefore, there is a requirement for some leakage through the input coupling capacitor 5 or biasing by an alternative method.

To check the response with leakage present, the input coupling capacitor 5 was replaced with an ultra-low leakage polystyrene capacitor in parallel with a 10 MΩ resistor. The results for the 50% threshold are shown in FIG. 11.

The ‘VC only’ trace in FIG. 11 is for the situation where the DC input voltage is connected directly to the varicap 14 and is included only as a reference. The ‘Cᵢₙ=0’ trace was taken with no coupling capacitance placed in parallel with the 10 MΩ leakage resistance. These results are largely what would be expected. The larger the coupling capacitance, the larger the response. This is logical since a larger input capacitance value will result in a smaller portion of the input voltage appearing across capacitor 5 and therefore proportionately more across the sensitive element (the varicap diode 14). Large values of input capacitance give virtually the same response as that seen when the input voltage is connected directly to the varicap 14. While the response at 10 pF is noticeably less, the important point is that there is a response, and importantly, that it is repeatable. This is significant because this is at the lower end of the capacitance range that would be desired. Although these results were taken with a leakage resistance artificially added in parallel with the coupling capacitance and are thus not a true representation of how the system would work in reality, they do illustrate an important point; the leakage is only required to bias the varicap diode 14, while the coupling capacitance value affects the quality of the response. Note that with leakage and no capacitance, there is virtually no response.

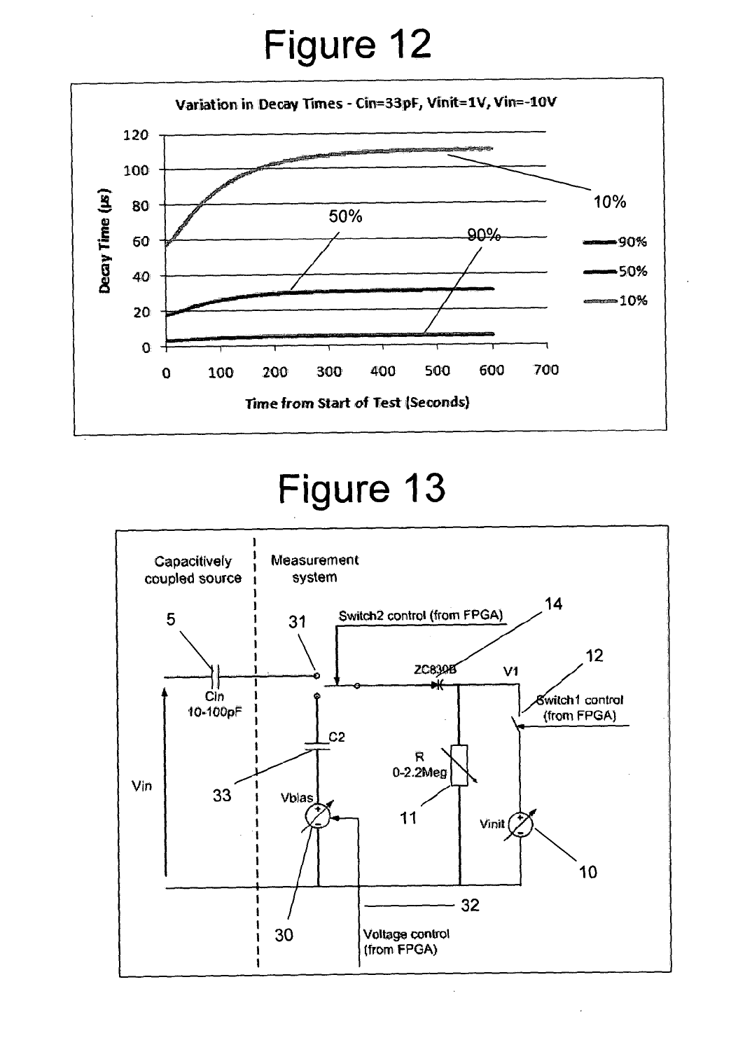

To use a real system, it is necessary for the device to work without the artificially added leakage resistor. When this was removed, it was observed that the decay curves changed in the expected manner when the DC input voltage was varied, but unfortunately it always drifted back to a default curve over time. Correspondingly, the measured decay times always defaulted to the same values when the test was repeated over a long period of time with the same DC voltage applied. This is shown in FIG. 12—the drift makes the device less preferred as a sensor without modification as measurements are not repeatable.

It was however noted that if the input voltage was initially strongly positive, then moved quickly to another voltage level and the reading immediately taken, then the response appeared reasonably consistent. As a result of this observation, the circuit was modified as shown in FIG. 13 such that a controllable bias voltage source 30 (generating a voltage V_{bias}) could be switched in by a switch 31 immediately prior to making a measurement.

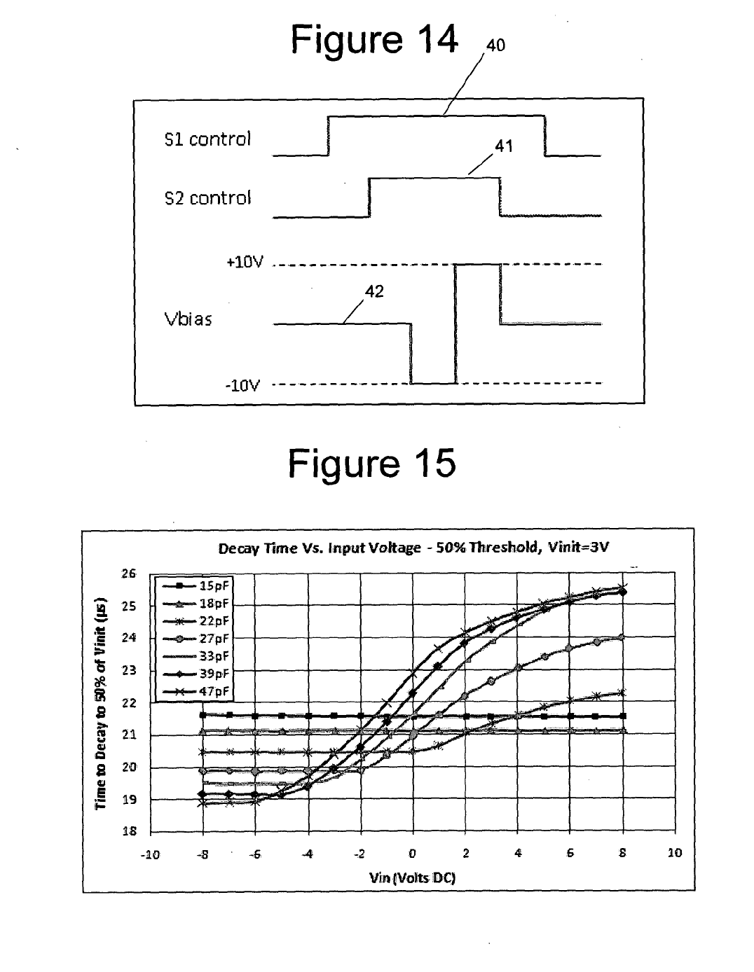

Bias voltage source 30 is implemented in such a way that the FPGA 25 can set it to different voltages as required via a voltage control line 32. It was found that the best way of applying the biasing voltage was to close switch 12 as normal, then connect switch 31 to a capacitor 33 (with a capacitance C2) in series with the bias voltage source 30. V_{bias} was then set strongly negative for 50 ms then strongly positive for 50 ms, before setting switch 31 to connect to capacitor 5. There was then a programmed delay, before finally opening switch 12 to begin the decay. The waveforms for Vbias and the timing sequence were derived empirically, and the sequence is shown in FIG. 14 where 40 indicates the control signal (S1 control) operating the first switch 12, 41 indicates the control signal (S2 control) operating the second switch 31, and 41 indicates Vbias. It should be noted at this point that both switches 12, 31 are CMOS types, meaning that the system is entirely electronic with no moving parts.

With this in place, it was found that a repeatable measurement could be obtained. Results with Vᵢₙᵢₜ=3V are shown in FIG. 15 (again only the results for the 50% threshold are shown, since those for 90% and 10% are effectively scaled copies of this). Each datapoint was obtained by taking the average of 100 measurements, and it was found that the curves were the same regardless of whether the input voltage was swept from −10V to +10V or vice versa.

It can be seen that the results follow the general trend of the others, but with some notable differences. Larger values of Cᵢₙ give a better response, as expected. Previously, the response was reasonably flat for large negative input voltages, and this is the case with these results also. However, previous results were plotted only with negative voltages since positive voltages caused the varicap 14 to become forward biased which prevented normal circuit operation. For the results from this modified circuit though, this is not the case, and a response can be seen over a range of positive and negative voltages. The reason for this is that the bias voltage source 30, controlled by the FPGA and coupled in via capacitor 33 (C₂), causes the varicap 14 to be biased at a particular point when switch 31 is in the lower position (FIG. 13). When switch 31 is then set to its upper position and the voltage source that is being measured is coupled in via capacitor 5, this modifies the pre-existing bias. In the previous setup with leakage, the bias was set by the DC source being monitored rather than being modified by it. Thus, over the voltage range shown in FIG. 15, the reverse bias condition can be maintained. The general trend is the same as before and as predicted by theory—as the input voltage being measured is made more positive, the time to decay to the threshold level becomes greater.

In addition, it is clear that with this configuration, there is no response for input coupling capacitance values less than 20 pF. This compares unfavourably with the results obtained with artificial leakage present, where a response could be seen for values as low as 10 pF. This difference comes about because of the additional circuitry—switch 31 has capacitance to ground from all terminals and these additional parasitic elements inevitably act to degrade performance. However, electrode-to-conductor capacitances of 20-30 pF are not problematic to achieve with a practically sized electrode.

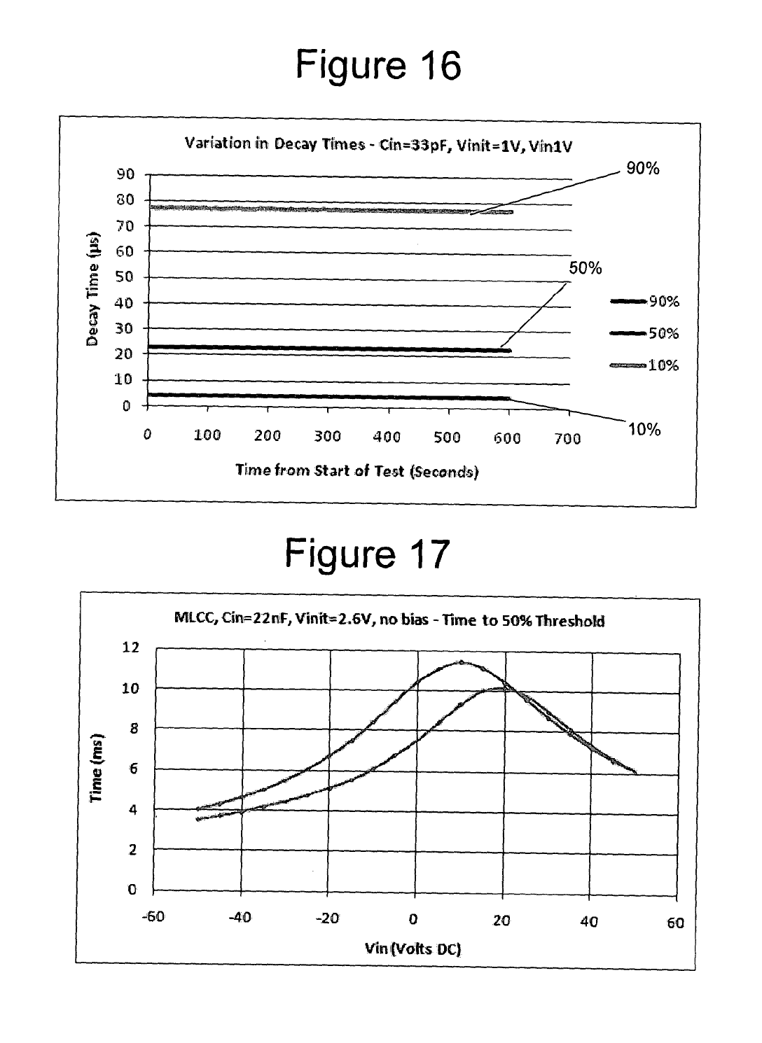

Without the additional controlled voltage source to pre-bias the varicap, it was seen that there was significant drift. With pre-biasing in place however, the device shows good stability and measurements are repeatable. There is no dependence on previous values of input voltage. FIG. 16 shows how the recorded decay times change as this circuit is left over the same period as in FIG. 12, with the same input voltage applied.

Clearly there is very little variation in this case, and analysis over a longer period of time reveals no deviation from this. The same is true when the system is switched off then on again, and also after any of the capacitors have been shorted out temporarily—for a given value of input voltage, the output is always the same, which is a notable improvement from the previous version that did not include capacitively coupled biasing.

Unlike the varicap, an MLCC does not require any reverse bias condition to make it function as a non-linear capacitor. It is therefore possible to include it as the non-linear element in the circuit of FIG. 9 without any need for biasing circuitry. The circuit was set up with the GRM188F51H473ZA01D component with base capacitance 47 nF for the non-linear element, just as in the previous section on modelling. Being rated at 50V, the circuit was tested with an input voltage range of −50V to +50V. The result of this, with a Cᵢₙ value of 22 nF is shown in FIG. 17, with the input voltage swept from −50V to +50V, then back to −50V.

Clearly this is undesirable as a sensor as the decay time is seen to be dependent upon previous Vᵢₙ values. This comes about as a result of the ferroelectric properties of the dielectric; the dielectrics of non-compensated MLCCS are ferroelectric by nature, and it is this that causes the non-linearity that is key to the sensor's operation. A capacitor with a ferroelectric dielectric will experience remnant polarisation, i.e. it will still store some charge even after the electric field is removed and its voltage is zero. The plot of charge against voltage for such a capacitor is not a straight line or a simple curve, but a hysteresis loop. Although the published data for the component does not show this, it is the case in all such dielectrics. With ferroelectric materials there is always a dependence on previous polarisation states, which is what is seen here.

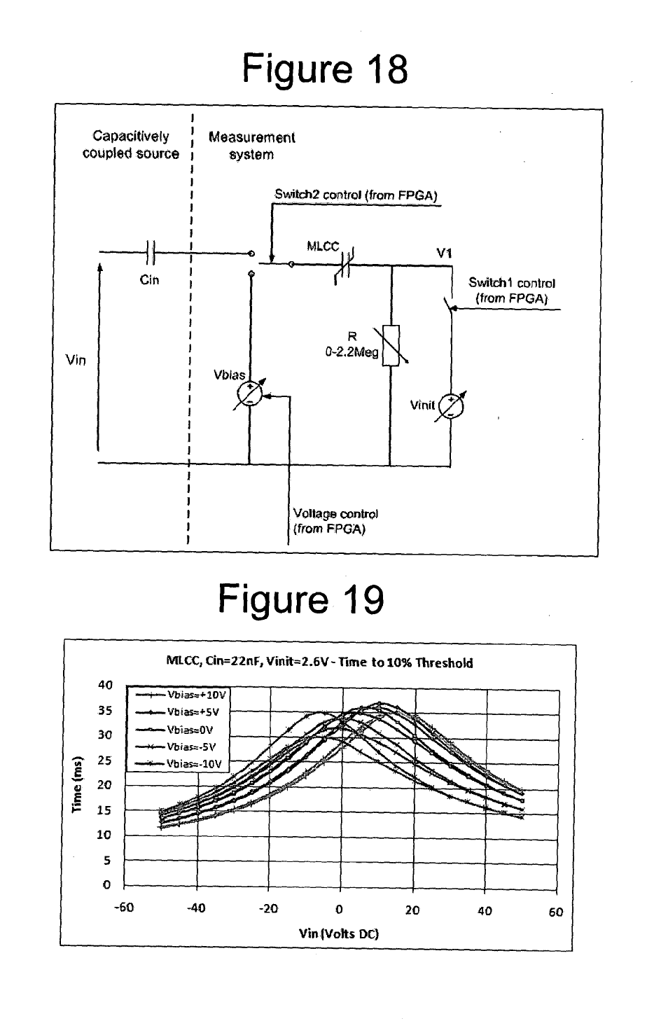

To mitigate this, it is possible to use a similar pre-biasing technique, similar to that used with the varicap. The aim of any pre-biasing is to put the MLCC into the same state before every measurement, so that previous states make no difference. This time, the biasing voltage is connected directly rather than being capacitively coupled as this worked better, with the modified circuit shown in FIG. 18. With a single bias voltage level applied before measurement, a typical set of results for Cᵢₙ=22 nF is shown in FIG. 19.

From these results it is clear that hysteresis in these results can be reduced by the application of suitable pre-biasing voltages. Although in this case there is no curve that reduces hysteresis to the extent that it could be used over the full voltage range, results show the device to be capable of working over part of the range—with the bias voltage set at −10V it could operate over the range 30V to 50V and with a bias voltage of 0V it is capable of operating in the range −50V to −10V. Ideally, it would be preferable for the pre-bias voltage to be larger, so as to force the ferroelectric material into its saturation state. This could not be done with the components of this circuit because the saturation voltage was in excess of 50V and the analogue switches could withstand a maximum value of only 15V. Should a ferroelectric capacitor with a lower voltage rating be produced however, the saturation voltage would be within the switch's range. Overall, these results compare well with theoretical results from modelling, and illustrate that the principle of using a non-linear capacitor applies generally and not specifically to one particular type of non-linear component.

In the embodiment of FIG. 19, pre-biasing is used to solve the hysteresis problem with the MLCC, but in an alternative embodiment (not shown) an alternative method may be used to solve the hysteresis problem. For example the MLCC could be heated to a temperature above or near its Curie temperature (which is the temperature to which the material must be heated to eliminate any remnant polarisation). Alternatively, a ferroelectric material can be chosen with a very narrow hysteresis loop which would not need either pre-biasing or heating.

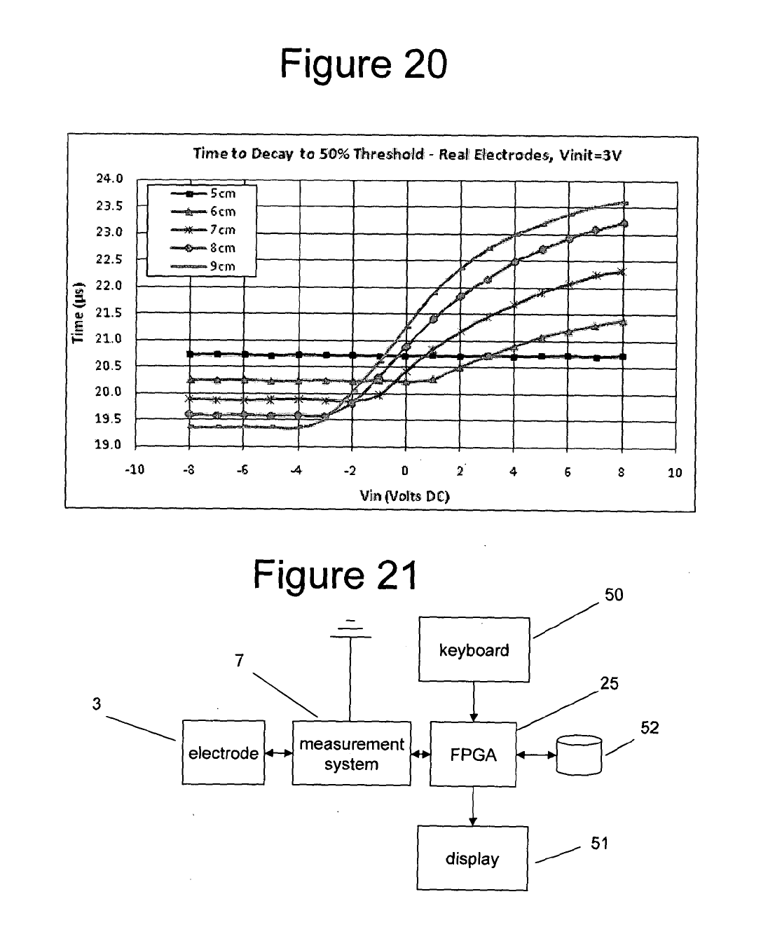

The previous results with the varicap diode were obtained with low leakage polystyrene capacitors, which suitably represent the coupling capacitance between conductor and electrode. However, in order to show that the desired response could indeed be achieved with real electrodes, these were made and the system tested with them. In this situation the input voltage being measured was applied to an insulated conductor, and the electrode was added to the outside of the insulation layer. Originally these electrodes were made by simply wrapping a layer of copper tape around the outside of the insulation, but it was found that conductor-to-electrode capacitance can be maximised by applying a layer of silver paint to the outside of the conductor, then wrapping copper tape on top of this. This combination means the electrode is applied around the full surface area of the conductor, rather than leaving the air gaps that are inevitable if copper tape alone is used. Measurement of the actual capacitance values of such an arrangement using an LCR meter revealed a capacitance per unit length of about 4 pF/cm. The responses for different electrode lengths are shown in FIG. 20.

From these results, it can be seen that capacitors formed by placing real electrodes around conductors do indeed give the same response as polystyrene capacitors. The 5 cm electrode gives virtually no response, but this is expected given previous results, since the capacitance for this electrode is about 20 pF. All larger electrodes give an acceptable response, and again, this is repeatable.

This work has proven the theory that R-C decay characteristics can be modified by an applied DC voltage if a non-linear capacitor is included in the circuit, therefore, a DC voltage can be measured without contacting the conductor in question if the decay curve is analysed. Modelled and experimental results have shown that any suitable non-linear capacitor can be used for the purpose, and with a low-capacitance varicap diode, the device is viable as a low DC voltage sensor. This appears to be the first time DC voltages have been measured by monitoring R-C decay in a non-linear capacitor circuit, and results show that with readily available commercial electronic components, DC voltages can be resolved to significantly less than 1V.

FIG. 21 is a schematic diagram of a sensor for measurement of a DC voltage of a DC voltage source, using the circuitry described above. The apparatus can be used in conjunction with a current sensor (not shown) to yield both impedance and power measurements. The sensor can be used in any application in which it is desirable to measure a DC voltage without having physical access to the conductor. For instance the sensor may be used to monitor aircraft wiring.

The electrode 3 and FPGA 25 are connected to a grounded measurement system 7 as described above with reference of FIG. 9, 13 or 18. The FPGA 25 is connected to a keyboard 50 (or other input device); a display 51 (or other output device) and a memory 52. The memory contains data giving decay time vs Vᵢₙ for a range of value of Cᵢₙ. In an initial calibration routine the electrode 3 is mounted on a wire carrying a known voltage Vᵢₙ and the decay time is measured to determine Cᵢₙ for that wire. Once Cᵢₙ is known for a given wire, then the voltage on that wire (or similar wires) can be subsequently measured by the sensor. That is, in a subsequent measurement the FPGA 25 determines the decay time, and looks up in memory 52 the voltage associated with that decay time and the known value of Cᵢₙ.

Although the invention has been described above with reference to one or more preferred embodiments, it will be appreciated that various changes or modifications may be made without departing from the scope of the invention as defined in the appended claims.

1. Apparatus for measurement of a DC voltage of a DC voltage source, the apparatus comprising an electrode for forming a capacitive connection with the DC voltage source; a non-linear capacitor having a first node connected to the electrode; an initial voltage source arranged to generate an initial voltage; a switch arranged to selectively apply the initial voltage to a second node of the non-linear capacitor; a voltage sensor arranged to measure the voltage of the second node of the non-linear capacitor; and a processor programmed to deduce the DC voltage of the DC voltage source by analysing the rate of decay of the measured voltage.

2. The apparatus of claim 1 further comprising biasing means arranged to selectively apply a bias voltage to the first node of the non-linear capacitor.

3. The apparatus of claim 2 wherein the biasing means is arranged to sequentially apply negative and positive bias voltages to the first node of the non-linear capacitor.

4. The apparatus of claim 1 further comprising a bias voltage source; and a switch arranged to selectively connect the bias voltage source to the first node of the non-linear capacitor.

5. The apparatus of claim 4 wherein the bias voltage source is arranged to sequentially generate negative and positive bias voltages.

6. The apparatus of claim 1 wherein the non-linear capacitor is a varicap diode or a non-compensated multilayer ceramic capacitor.

7. The apparatus of claim 1 wherein the non-linear capacitor has a capacitance which is less than 100 pf, more typically less than 20 pf, and most preferably less than 10 pf.

8. The apparatus of claim 1 wherein the switch is a transistor switch.

9. A method of measuring a DC voltage of a DC voltage source, the method comprising arranging an electrode to form a capacitive connection with the DC voltage source; providing a non-linear capacitor having a first node connected to the electrode; generating an initial voltage with an initial voltage source; closing a switch to connect the initial voltage source to a second node of the non-linear capacitor so the initial voltage is applied to the second node of the non-linear capacitor; opening the switch to disconnect the non-linear capacitor from the initial voltage source; measuring the voltage of the second node of the non-linear capacitor after the switch has been opened; and deducing the DC voltage of the DC voltage source by analysing the rate of decay of the measured voltage.

10. The method of claim 9 further comprising generating a bias voltage with a bias voltage source; pre-biasing the non-linear capacitor by applying the bias voltage to the first node of the non-linear capacitor; and removing the bias voltage from the first node of the non-linear capacitor before the switch is opened to disconnect the non-linear capacitor from the initial voltage source.

11. The method of claim 10 wherein the bias voltage is applied by closing a bias switch to connect the bias voltage source to the first node of the non-linear capacitor after the initial voltage has been applied to the second node of the non-linear capacitor; and the bias voltage is removed by opening the bias switch to disconnect the bias voltage source from the first node of the non-linear capacitor.

12. The method of claim 10 further comprising sequentially varying the bias voltage which is applied to the first node of the non-linear capacitor between a positive voltage and a negative voltage.

13. The method of claim 10 wherein the rate of decay of the measured voltage is analysed by measuring the time taken for it to decay to a threshold level.

14. The method of claim 10 wherein the non-linear capacitor has a capacitance which is less than the capacitance of the capacitive connection with the DC voltage source.

15. The method of claim 10 wherein the capacitance of the capacitive connection with the DC voltage source is less than 1 nf, more typically less than 500 pf, and most preferably less than 100 pf.
